(19) United States
(12) Patent Application Publication
(10) Pub. No.: US 2008/0142970 A1
(43) Pub. Date: Jun. 19, 2008

(54) Nanowire chemical mechanical polishing

(75) Inventors: David R. Evans, Beaverton, OR (US); Lisa H. Stecker, Vancouver, WA (US); Allen Burmaster, Vancouver, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/638,928

(22) Filed: Dec. 14, 2006

(51) Int. Cl. H01L 21/768; H01L 23/48

(52) U.S. Cl. 257/741; 438/759; 257/E21.576; 257/E23.01; 977/762

(57) ABSTRACT

A planarized nanowire structure and a method for planarizing a nanowire structure are presented. The method provides nanowires with tips, formed overlying a substrate. A first insulator layer is deposited partially covering the nanowires. The first insulator layer is coated with a spin-on insulator layer, completely covering the nanowires. In some aspects of the method, the spin-on insulator layer is annealed. The spin-on insulator layer is then polished with a slurry and, in response to the polishing, a planarized insulator surface is formed with exposed nanowire tips.

### BACKGROUND OF THE INVENTION

1. Field of the Invention

This invention generally relates to integrated circuit (IC) fabrication and, more particularly, to a planarized nanowire structure and associated fabrication process.

2. Description of the Related Art

The processing of selectively grown nanostructures, such as ZnO nanowires, has proven difficult due to the physical fragility and chemical (pH) sensitivity of such structures. In the case of electrically conductive nanowires it would desirable if high aspect ratio nanowires could be formed to a uniform height, for interfacing with an overlying electrode. To address the fragility issue, the nanowires can be embedded in a fill or insulator material. However, the different selectivities of the nanowire and fill material make subsequent processing or exposure of the nanowires problematic.

It would be advantageous if a process existed that permitted nanowires to be embedded in an insulator for protection, while created a planarized insulator surface with exposed nanowires.

It would be advantageous if the above-mentioned planarized insulator surface could be fabricated using an etching process that was not selective to the nanowire and insulator materials.

### SUMMARY OF THE INVENTION

This present invention provides a method that improves support and integrity of high aspect ratio nanostructures, while preserving their optical properties. The method non-destructively fills the space between the nanostructures and then planarizes the structure through a chemical mechanical polish (CMP). The end product is a secure and protected nanostructure with exposed, planarized tips available for electrical contact and further processing, thus making them ideal for optical device components.

Accordingly, a method is provided for planarizing a nanowire structure. The method provides nanowires with tips, formed overlying a substrate. A first insulator layer is deposited partially covering the nanowires. The first insulator layer is coated with a spin-on insulator layer, completely covering the nanowires. In some aspects of the method, the spin-on insulator layer is annealed. The spin-on insulator layer is then polished with a slurry and, in response to the polishing, a planarized insulator surface is formed with exposed nanowire tips.

Typically, the first insulator layer has a thickness of about 10 nanometers (nm), or greater. The first insulator and spin-on insulator layer have a cumulative height of about 150 nm, or greater. In one aspect, the slurry has about a neutral pH. For example, the pH may be in a range of about 3 to 10 and, preferable, in a range of about 5 to 8. Cerium oxide is a material that is useful as a slurry material.

The spin-on insulator layer may be a material such as hydrogen silesquioxane (HSQ), methyl SQ (MSQ), alkyl SQ (ASQ), siloxane polymers, and any of the above mentioned materials doped with either boron or phosphorous. The first insulator may be silicon dioxide or an organic polyimide. The nanowires can be made from a material such as ZnO, IrOₓ, In₂O₃, SnO₂, carbon nanotube (CNT), indium tin oxide (ITO) TiO₂, InO, Sb₂O₃, Pd, Pt, Au, Mo, Si, Ge, SiGe, CdSe, AlN, ZnS, InP, or InAs.

Additional details of the above-described method and a planarized nanowire structure are described below.

### BRIEF DESCRIPTION OF THE DRAWINGS

FIG. 1 is a partial cross-sectional view of a planarized nanowire structure.

FIG. 2 is a partial cross-sectional view of a variation of the planarized nanowire structure depicted in FIG. 1.

FIGS. 3A through 3D are plans views depicting steps in the completion of the structures of FIGS. 1 and 2.

FIG. 4 is a flowchart illustrating a method for planarizing a nanowire structure.

### DETAILED DESCRIPTION

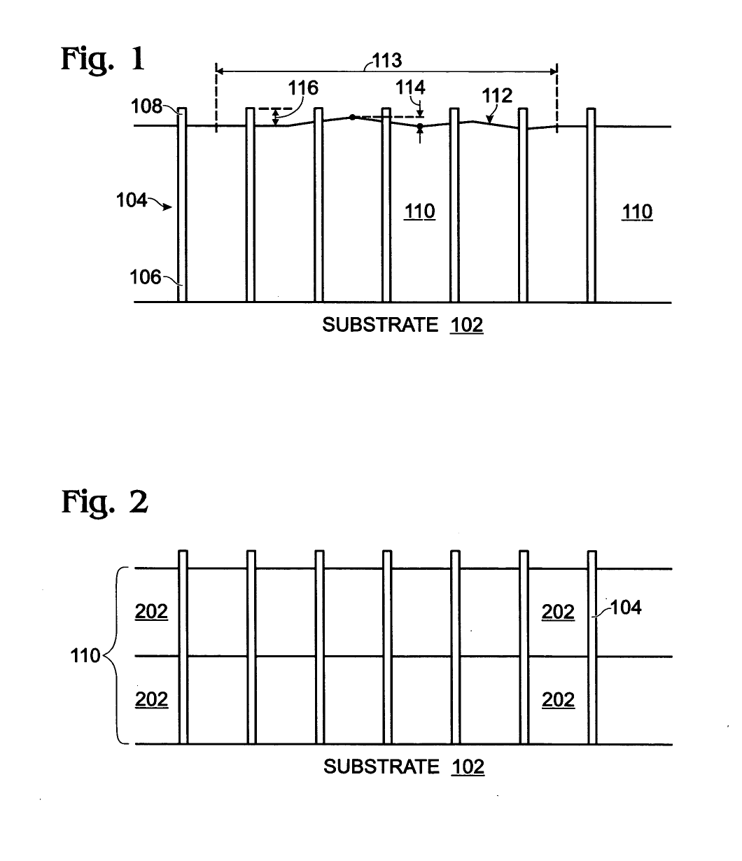

FIG. 1 is a partial cross-sectional view of a planarized nanowire structure. The structure 100 comprises a substrate 102. The substrate made be a transparent material such as quartz, plastic, or glass, a silicon-containing material, or an electrically conductive material, such as a metal, to name a few examples. The structure includes a plurality of nanowires 104. Each nanowire 104 has a distal end 106 attached to the substrate 102, and a tip 108. An insulator layer 110 overlies the substrate 102, with a planarized surface 112 having a surface roughness 114 of less than about 10 nanometers (nm) over an area 113 of at least 1 square millimeter. The nanowire tips 108 are exposed above the planarized surface 112 by a distance 116 of less than 100 nm.

More specifically, FIG. 1 depicts a structure where the insulator layer 110 is a first insulator made from a material such as silicon dioxide or an organic polyimide. However, other materials may also be used. The nanowires may be an electrically conductive or non-conductive material. Some examples of possible materials include ZnO, IrOₓ, In₂O₃, SnO₂, carbon nanotube (CNT), indium tin oxide (ITO) TiO₂, InO, Sb₂O₃, Pd, Pt, Au, Mo, Si, Ge, SiGe, CdSe, AlN, ZnS, InP, and InAs.

FIG. 2 is a partial cross-sectional view of a variation of the planarized nanowire structure depicted in FIG. 1. In this aspect, the insulator layer 110 includes a first insulator layer 200 overlying the substrate 102, as described above, and a spin-on insulator layer 202 overlying the first insulator layer 200. Since the first insulator layer 200 is not subjected to a polishing process (described below), a broader range of insulator materials, besides silicon dioxide and organic polyamides, are possible. The spin-on insulator 202 may be a material such as hydrogen silesquioxane (HSQ), methyl SQ (MSQ), alkyl SQ (ASQ), siloxane polymers, or any of the above-mentioned materials doped with either boron or phosphorous.

### FUNCTIONAL DESCRIPTION

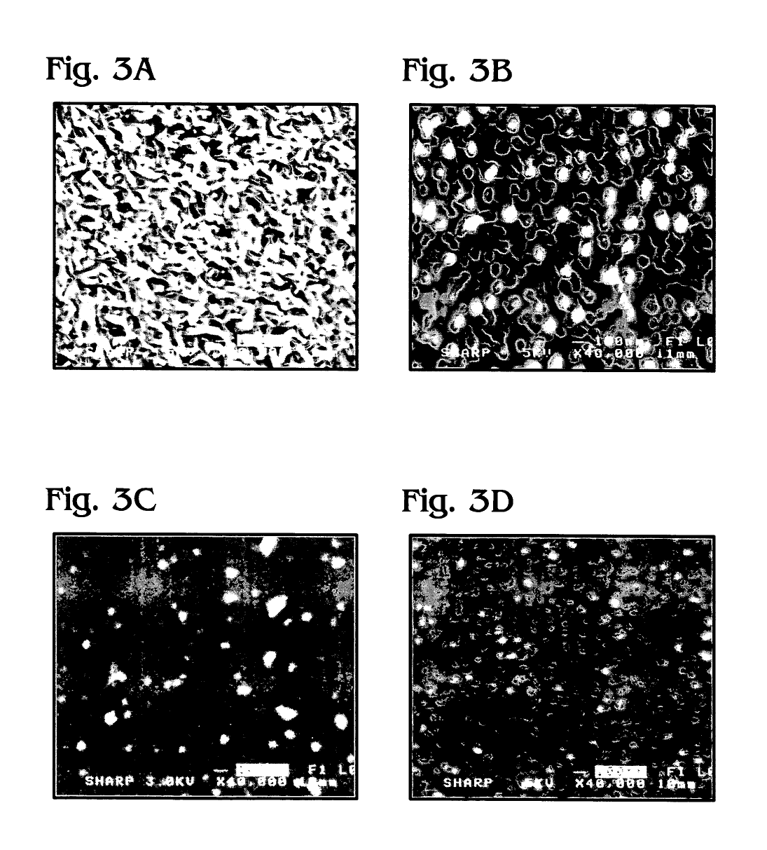

FIGS. 3A through 3D are plans views depicting steps in the completion of the structures of FIGS. 1 and 2. FIG. 3A depicts vertically aligned ZnO structures. In FIG. 3B the ZnO nanowires are coated with 10 nm, or more, of plasma-enhanced chemical vapor deposition (PECVD) SiO₂ in order to provide minimal physical support. The substrate is then coated with spin-on flowable insulator, such as HSQ or other suitable oxide polymer for example, so that the cumulative height of the two insulator layers is at least 150 nm greater than the desired height of the ZnO nanostructures after processing.

After applying the spin-on oxide, the substrate is annealed to sufficiently densify, drive off solvents, and enhance the Si—O—Si bonding, see FIG. 3C. This is achieved through treatment in a N₂ ambient at temperatures between 400-850° C., for 15-60 minutes, sufficient to achieve a continuous fill between the nanostructures.

Owing to the delicate nature of ZnO, as describe above, the pH of the polishing slurry is confined to a range around neutrality. In practical terms this covers a pH range of 3 to 10, with 5 to 8 being optimum. Outside of this range, i.e., using a more acidic or alkaline solution, the ZnO nanowires are attacked and dissolved during polishing. Accordingly, silica abrasives are not easily used for such a process since they agglomerate and form semi-solid gels in this pH range. Therefore, cerium oxide provides a suitable, but not the only alternative. Consequently, a polishing process may be used that operates in the stated pH range using conventional polyurethane pads, a conventional rotary polisher at spindle-table rotation rates from 0 to 500 rpm, and down force between 0 and 20 pounds per square inch (psi). Note: a down force of 0 psi is equivalent to non-selective etch process. A simple strong alkaline solution, with a pH>12, is an example of a non-selective etchant. The alkaline solution may be either aqueous or alcoholic.

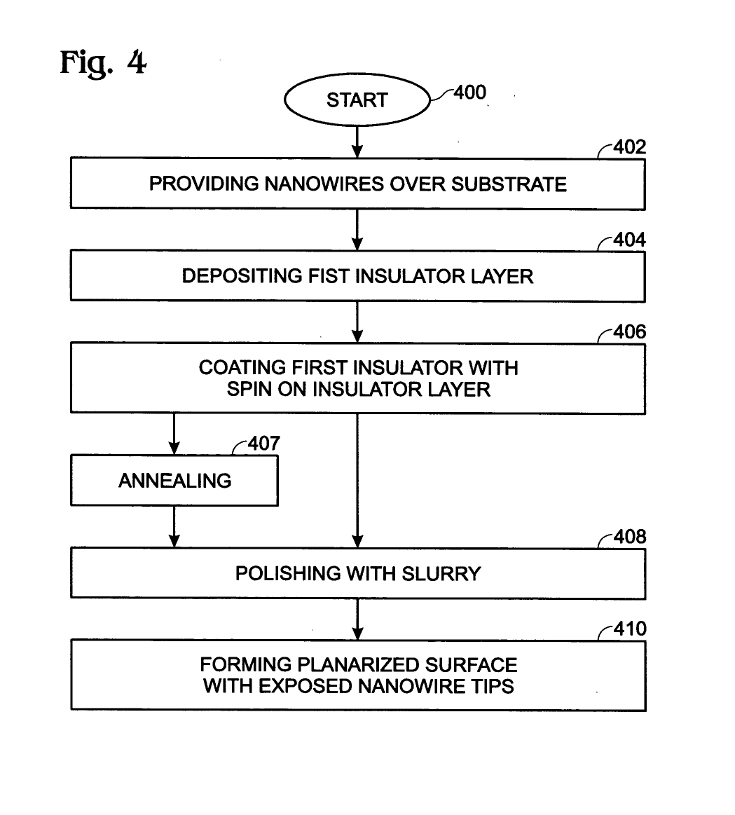

FIG. 4 is a flowchart illustrating a method for planarizing a nanowire structure. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 400.

Step 402 provides nanowires with tips, formed overlying a substrate. Some potential nanowire materials include ZnO, IrOₓ, In₂O₃, SnO₂, carbon nanotube (CNT), indium tin oxide (ITO) TiO₂, InO, Sb₂O₃, Pd, Pt, Au, Mo, Si, Ge, SiGe, CdSe, AlN, ZnS, InP, and InAs. Typically, the nanowires have an axis about normal (orthogonal) with respect to a top surface of the substrate. Step 404 deposits a first insulator layer partially covering the nanowires. Some examples of a first insulator material include silicon oxide, silicon dioxide, and organic polymers. If silicon dioxide is used, it may be deposited using a PECVD process.

Step 406 coats the first insulator layer with a spin-on insulator layer, completely covering the nanowires. The spin-on insulator may be HSQ, MSQ, ASQ, siloxane polymers, or any of these materials doped with either boron or phosphorus. Step 408 polishes the spin-on insulator layer with a slurry. In one aspect, the slurry has about a neutral pH. In this case, the pH is in the range of 3 to 11 and, more preferable, in the range of 5 to 8. Cerium oxide is one example of a useful slurry. For example, polishing the spin-on insulator layer with the slurry may include using a spindle-table rotation rate in the range of about 1 to 500 revolution pre minute (rpm), and a down force in the range of about 0 to 20 psi. In one aspect, polishing the spin-on insulator layer with the slurry includes polishing down to either the first insulator layer or the spin-on insulator layer. In response to the polishing, Step 410 forms a planarized insulator surface with exposed nanowire tips.

In one aspect, depositing the first insulator layer in Step 404 includes depositing the first insulator with a thickness of about 10 nm, or greater. In another aspect, coating the first insulator with the spin-on insulator in Step 406 includes forming a first insulator and spin-on insulator layer with a cumulative height of about 150 nm, or greater, overlying the nanowires.

In one aspect of the method, subsequent to coating with the spin-on insulator layer (Step 406), Step 407 anneals. For example, the annealing may be performed in a N₂ atmosphere, in a range of about 400 to 850° C., for a duration in a range of about 15 to 60 minutes. However, alternate ranges and combinations of ranges are also possible.

In a different aspect, forming a planarized surface with exposed nanowire tips in Step 410 includes forming a planarized surface with a surface roughness of less than about 10 nm over an area of at least 1 square millimeter, and exposing less than 100 nm of nanowire tip above the planarized surface.

A nanowire structure with a planarized surface, and corresponding fabrication process have been provided. Some examples of materials and process variables have been presented to illustrate the invention, However, the invention is not limited to merely these examples. Other variations and embodiments of the invention will occur to those skilled in the art.

We claim:

1. A method for planarizing a nanowire structure, the method comprising:
providing nanowires with tips, formed overlying a substrate:
depositing a first insulator layer partially covering the nanowires;
coating the first insulator layer with a spin-on insulator layer, completely covering the nanowires;
polishing the spin-on insulator layer with a slurry; and,
in response to the polishing, forming a planarized insulator surface with exposed nanowire tips.

2. The method of claim 1 wherein providing nanowires with tips includes providing nanowires with an axis about normal with respect to a top surface of the substrate.

3. The method of claim 2 wherein depositing the first insulator layer includes depositing the first insulator with a thickness of about 10 nanometers (nm), or greater.

4. The method of claim 3 wherein coating the first insulator with the spin-on insulator includes forming a first insulator and spin-on insulator layer with a cumulative height of about 150 nm, or greater, overlying the nanowires.

5. The method of claim 2 wherein polishing the spin-on insulator layer with the slurry includes polishing with a slurry having a pH in a range of about 3 to 10.

6. The method of claim 5 wherein polishing the spin-on insulator layer with the slurry includes polishing with a slurry having a pH in a range of about 5 to 8.

7. The method of claim 2 wherein polishing the spin-on insulator layer with the slurry includes polishing with cerium oxide slurry.

8. The method of claim 2 wherein polishing the spin-on insulator layer with the slurry includes:
using a spindle-table rotation rate in the range of about 1 to 500 revolution pre minute (rpm); and,
using a down force in the range of about 0 to 20 pounds per square inch (psi).

9. The method of claim 1 where depositing the first insulator layer includes depositing silicon dioxide using a plasma-enhanced chemical vapor deposition (PECVD) process.

10. The method of claim 1 wherein coating with a spin-on insulator layer includes coating with a material selected from a first group consisting of hydrogen silesquioxane (HSQ), methyl SQ (MSQ), alkyl SQ (ASQ), siloxane polymers, and a first group material doped with a dopant selected from a group consisting of boron and phosphorous.

11. The method of claim 1 further comprising:
subsequent to coating with the spin-on insulator layer, annealing.

12. The method of claim 11 wherein annealing includes:
annealing in a N₂ atmosphere;
annealing with a temperature in a range of about 400 to 850° C.; and,
annealing for a duration in a range of about 15 to 60 minutes.

13. The method of claim 1 wherein providing nanowires includes providing nanowires made from a material selected from a group consisting of ZnO, IrOₓ, In₂O₃, SnO₂, carbon nanotube (CNT), indium tin oxide (ITO) TiO₂, InO, Sb₂O₃, Pd, Pt, Au, Mo, Si, Ge, SiGe, CdSe, AlN, ZnS, InP, and InAs.

14. The method of claim 1 wherein depositing the first insulator includes depositing an insulator selected from a group consisting of silicon dioxide and organic polyamides.

15. The method of claim 1 wherein forming a planarized surface with exposed nanowire tips includes:
forming a planarized surface with a surface roughness of less than about 10 nm over an area of at least 1 square millimeter; and,
exposing less than 100 nm of nanowire tip above the planarized surface.

16. The method of claim 1 wherein polishing the spin-on insulator layer with the slurry includes polishing down to a layer selected from a group consisting of the first insulator layer and the spin-on insulator layer.

17. A planarized nanowire structure, the structure comprising:
a substrate:
a plurality of nanowires, each nanowire having a distal end attached to the substrate, and a tip;
an insulator layer overlying the substrate, with a planarized surface having a surface roughness of less than about 10 nanometers (nm) over an area of at least 1 square millimeter; and,
wherein the nanowire tips are exposed above the planarized surface by a distance of less than 100 nm.

18. The structure of claim 17 wherein the insulator layer is a material selected from a group consisting of silicon dioxide and organic polyamides.

19. The structure of claim 17 wherein the insulator layer includes a first insulator layer overlying the substrate and a spin-on insulator layer overlying the first insulator layer, where the spin-on insulator is a material selected from a first group consisting of hydrogen silesquioxane (HSQ), methyl SQ (MSQ), alkyl SQ (ASQ), siloxane polymers, and a first group material doped with a dopant selected from a group consisting of boron and phosphorous.

20. The structure of claim 17 wherein the nanowires are a material selected from a group consisting of ZnO, IrOₓ, In₂O₃, SnO₂, carbon nanotube (CNT), indium tin oxide (ITO) TiO₂, InO, Sb₂O₃, Pd, Pt, Au, Mo, Si, Ge, SiGe, CdSe, AlN, ZnS, InP, and InAs.
